(19) United States
(12) Patent Application Publication
(10) Pub. No.: US 2010/0315089 A1
(43) Pub. Date: Dec. 16, 2010

(54) SYSTEM AND METHOD FOR BATTERY CHARGER SELF TEST AND DIAGNOSTIC MEANS

(75) Inventor: Mark Rapich, Westfield, IA (US)

Correspondence Address: SUITER SWANTZ PC LLO, 14301 FNB PARKWAY, SUITE 220, OMAHA, NE, 68154, US

(73) Assignee: LESTER ELECTRICAL, Lincoln, NE (US)

(21) Appl. No.: 12/485,578

(22) Filed: Jun. 16, 2009

(51) Int. Cl. G01R 31/00; G01N 27/416

(52) U.S. Cl. 324/426

(57) ABSTRACT

A self diagnostic battery charging system may include a battery charger and a diagnostic module having a power supply separate from the battery charger. Additionally, a method may include executing a diagnostic program and indicating a result from the diagnostic program.

### TECHNICAL FIELD

The present disclosure generally relates to the field of battery chargers, and more particularly to systems and methods for self testing and diagnosing a battery charger.

### BACKGROUND

A battery may include a combination of two or more electrochemical cells that store chemical energy and make the chemical energy available as electrical energy. Some batteries may include secondary cells, or rechargeable batteries. A rechargeable battery may include an electrochemical cell in which the electrochemical reaction that releases energy is readily reversible.

A battery charger may include an electrical appliance used to put energy into a rechargeable battery by forcing an electric current through the rechargeable battery in the direction opposite to that of the discharge current. During charging, the positive active material is oxidized, which produces electrons, and the negative material is reduced, consuming electrons. Many types of battery chargers exist, including trickle types, intelligent types, and/or inductive types. Some battery chargers are used for mobile phone batteries, car batteries, and camera batteries, while others may have more industrial applications, such as for electric vehicles, forklifts, aerial work platforms, and floor scrubbers. Batteries are the only source of power for this equipment and must be recharged after each use. Significant costs may be incurred to diagnose poor system performance.

### SUMMARY

A self diagnostic battery charging system may include a battery charger, a diagnostic self test circuit, a first and second power supply, and/or at least one diagnostic indicator.

A method may include receiving an indication of a triggered test button configured for initializing a battery charger diagnostic self test circuit, where the triggered test button is communicatively coupled to a battery charger, the battery charger is coupled to a first power source, and the triggered test button and the battery charger diagnostic self test circuit are coupled to a second power source, executing a diagnostic program for testing the battery charger subsequent to receiving an indication of a triggered test button, determining a status of the battery charger from execution of the diagnostic program, and/or indicating at least one result from the diagnostic program on at least one diagnostic indicator.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

The numerous advantages of the disclosure may be better understood by those skilled in the art by reference to the accompanying figures in which:

FIG. 1 is an environmental diagram illustrating a self diagnostic battery charging system.

FIG. 2 is an environmental diagram illustrating a self diagnostic battery charging system.

FIG. 3 is an flow diagram illustrating a method for a battery system self test and diagnosis.

### DETAILED DESCRIPTION

Reference will now be made in detail to the subject matter disclosed, which is illustrated in the accompanying drawings.

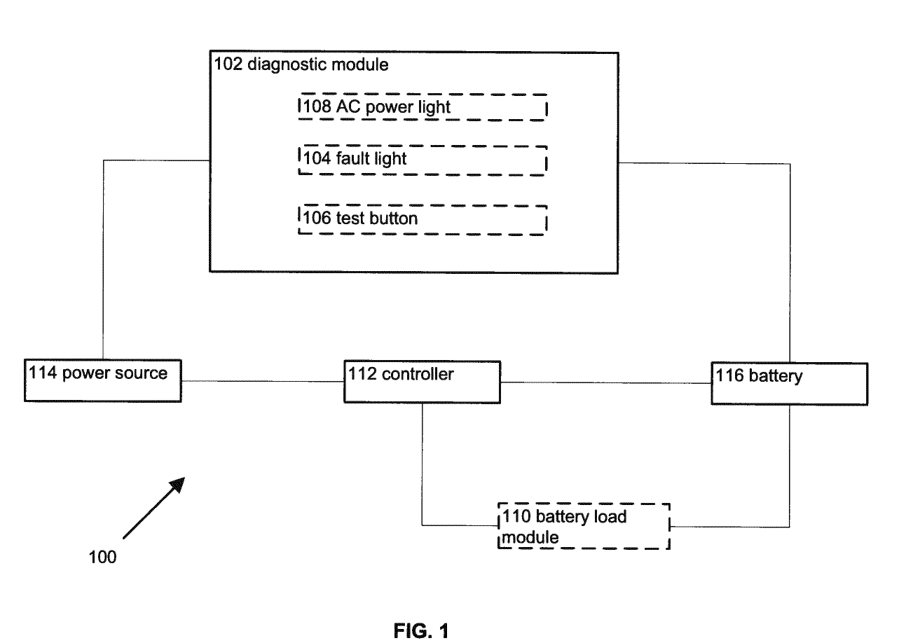

Referring generally to FIGS. 1 through 3, a self test diagnostic circuit 100 and a method 300 utilizing the self test diagnostic circuit 100 are described. The self test diagnostic circuit 100 may include a battery charger including a controller 112, a display 206, input means 202, a diagnostic module 102, and/or a diagnostic indicator. Method 300 may include receiving an indication of a triggered test button configured for initializing a battery charger diagnostic self test circuit, where the triggered test button is communicatively coupled to a battery charger, the battery charger is coupled to a first power source, and the triggered test button and the battery charger diagnostic self test circuit are coupled to a second power source, executing a diagnostic program for testing the battery charger subsequent to receiving an indication of a triggered test button, determining a status of the battery charger from execution of the diagnostic program, and/or indicating at least one result from the diagnostic program on at least one diagnostic indicator. In an embodiment, a microprocessor controlled battery charger may include a control board and/or a controller 112, a means to convert AC power to DC power with the proper current and voltage to charge a battery, a display 206 and/or input devices and/or input means 202 to operate the charger, and output cables and to transfer the DC power to the battery 116.

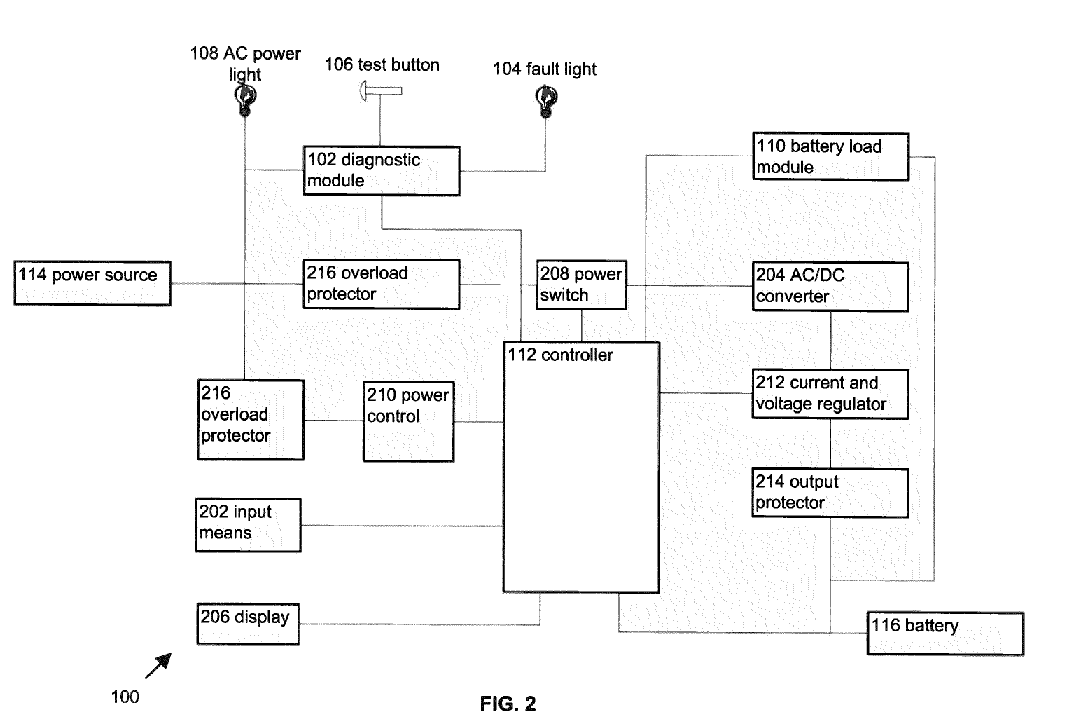

As shown in FIGS. 1 and 2, the self test diagnostic circuit system 100 may include diagnostic module 102. Diagnostic module 102 may include fault light 104, test button 106, and/or AC power light 108. Additionally, diagnostic module 102 may include means for diagnosing a battery circuit, such as a computer processor and/or a series of diagnostic circuits and/or software. Fault light 104 and/or AC power light 108 may include a visual indicator and may be hardwired to controller 112 and/or coupled to a CPU via a general I/O port. One example of a visual indicator may include a light emitting diode (LED). Additionally, a visual indicator may be positioned to be externally readable, for example, on a front panel of the self test diagnostic circuit system 100. In some instances, a visual indicator may be internally readable, such as only when an access cover is removed. In an embodiment, fault light 104 and/or AC power light 108 may include a flash circuit for providing a flashing visual indication when there may be a problem and/or other status indication, such as no AC power, a fault, and/or other malfunction.

A special test circuit including diagnostic module 102 and test button 106 may be used with an independent power supply for providing a failsafe fault indicator. When the test button 106 is pushed, a simple circuit may turn on fault light 104 and may keep it on so that it stays on when test button 106 is released. An additional function of test button 106 may include communicating to the controller 112 that the self-test is invoked. In normal operation, controller 112 may execute a special diagnostic program that tests all charger functions, and when successful, turn off the fault light 104 and indicate a test complete on display 206. If the controller 112 or any other charger circuits are not operating properly, fault light 104 may remain illuminated. If the controller 112 is capable of operation but other parts of the charger are defective, the controller 112 may display an error code or test message that may describe the failed parts and/or fault.

Self test diagnostic circuit system 100 may include a separate special circuit, such as battery load module 110 for performing an electronic battery load to test the charger output for proper voltage and current. The battery load module 110 may calibrated when the charger and/or self test diagnostic circuit system 100 is built and tested. The calibration information may be stored in controller 112.

Controller 112 may include a digital controller configured to control the operation of a battery charger and/or self test diagnostic circuit system 100. Controller 112 may control the power input, such as the frequency of the alternating current, and may be powered by the input power. Additionally, controller 112 may be communicatively coupled to diagnostic module 102, battery load module 110, power source 114, power switch 208, power control 210, input means 202, display 206, AC/DC converter 204, current and voltage regulator 212, output protection 214, and/or battery 116.

Power source 114 may include an alternating current (AC) power source and/or a direct current (DC) source. For example, power source 114 may include a 3 phase 60 Hz 480 volt AC power source. In another example, power source 114 may include a 270 volt DC power source. The amount and/or range of power from power source 114 may be software selectable and dependent on the native power grid infrastructure. Additionally, self test diagnostic circuit system 100 may include power switch 208 and/or power control 210. Power switch 208 may include an on-off switch configured to break an electric circuit. Power control 210 may include a controller having circuitry for receiving input from controller 112, providing a predetermined voltage and current, and/or activating power switch 208. Power control 210 may include additional functionality, such as providing power to diagnostic module 102 separately from power directed to the battery 116 and/or battery charger.

The power for charging battery 116 may be at least partially determined by current and voltage regulator 212. Current and voltage regulator 212 may include a voltage regulator, which may be designed to maintain a constant voltage level either through an electromechanical mechanism and/or by passive or active electrical components. Further, current and voltage regulator 212 may include a current regulator, such as a constant current diode.

Self test diagnostic circuit system 100 may further include output protector 214 and/or overload protector 216. Output protector 214 and/or overload protector 216 may include a device designed to protect a system and/or electrical device from a voltage spike. One example of output protector 214 and/or overload protector 216 may include a surge protector.

Many different battery chemistries exist with many different optimum charge requirements for voltage and current during the charge. These charge profiles may be quite complex for optimum battery capacity and life. A battery 116 may include a rechargeable battery. A rechargeable battery may include at least one electrochemical cell which may be recharged by applying electrical energy. Some examples of a rechargeable battery may include lead acid, nickel cadmium (NiCd), nickel metal hydride (NiMH), lithium ion (Li-ion), and lithium ion polymer (Li-ion polymer).

Self test diagnostic circuit system 100 may include input means 202 for providing input to controller 112 and/or the self test diagnostic circuit system 100. For example, self test diagnostic circuit system 100 may include a keyboard and monitor for inputting operational parameters in the controller. In another example, self test diagnostic circuit system 100 may include an LCD touchscreen. Some other examples of input means may include a network connection, such as Ethernet or a wireless connection, and/or input from a memory device, such as a USB drive or ROM memory.

Controller 112 may be communicatively coupled to AC/DC converter 204. AC/DC converter 204 may include a device for converting AC power to DC power, such as a rectifier, or for converting DC power to AC power, such as an inverter. In an example, self test diagnostic circuit system 100 may include controller 112 operably coupled to an AC/DC converter including a rectifier.

Self test diagnostic circuit system 100 may include a display 206. Display 206 may include a device as simple as a single light capable of communicating a result, such as a fault and/or normal operation of a battery charger. Further, display 206 may include other devices, such as a touchscreen, a computer monitor, and/or a printer. In an example, display 206 may include a touchscreen LCD monitor capable of displaying messages, an error code, and/or a system status.

In an embodiment, normal operation of a battery charger and/or a diagnostic module may include plugging a battery operated vehicle into the battery charger when the batteries need charging. The battery charger may automatically sense the battery and charge it, or an operator may be required to initiate the charge by controlling the charger via input means. The charger may charge the battery by supplying a controlled DC current until certain battery conditions of voltage or current are met, which indicate a fully charged battery. Additionally, a battery may contain a controller configured for informing the battery charger how much energy is required to fully charge the battery.

By the operation of the above elements, the charger operation and the AC Power to the charger may be verified and indicated to the operator, such as via a touchscreen and/or LCD monitor. In addition, the combination of fault and error information may indicate to a service technician or operator a required course of action and/or specific component malfunction if a fault exists. After servicing and/or repair, the technician may verify that the output of the charger matches factory calibration.

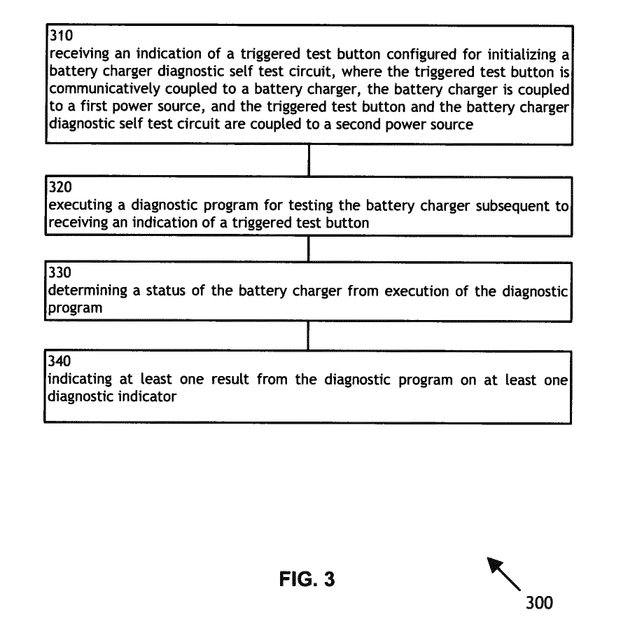

As illustrated in FIG. 3, method 300 for a battery charger diagnosis is illustrated. Operation 310 recites receiving an indication of a triggered test button configured for initializing a battery charger diagnostic self test circuit, where the triggered test button is communicatively coupled to a battery charger, the battery charger is coupled to a first power source, and the triggered test button and the battery charger diagnostic self test circuit are coupled to a second power source.

Operation 320 recites executing a diagnostic program for testing the battery charger subsequent to receiving an indication of a triggered test button. A diagnostic program may include a set of instructions and/or an algorithm configured to perform a diagnosis on a battery charger. Operation 330 recites determining a status of the battery charger from execution of the diagnostic program. Determining may include checking operational status of a controller, a battery, and/or a power supply. Operation 340 recites indicating at least one result from the diagnostic program on at least one diagnostic indicator. One example of indicating a result may include displaying an error code on a screen and/or monitor. Another example may include lighting a fault light, such as a red LED.

In the present disclosure, the methods disclosed may be implemented as sets of instructions or software readable by a device. Further, it is understood that the specific order or hierarchy of steps in the methods disclosed are examples of exemplary approaches. Based upon design preferences, it is understood that the specific order or hierarchy of steps in the method can be rearranged while remaining within the disclosed subject matter. The accompanying method claims present elements of the various steps in a sample order, and are not necessarily meant to be limited to the specific order or hierarchy presented.

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes.

What is claimed is:

1. A self diagnostic battery charging system, comprising:
a battery charger including
a control board including a controller configured to execute a diagnostic program,
a display,
an input device,
means for converting AC power to DC power configured to provide power to charge a battery, and
at least one output cable configured to be operably coupled to and transfer DC power to the battery;
a battery charger function test button configured to test at least one of a display operation or an internal circuit;
a diagnostic self test circuit including a fault indicator configured to be initiated by a battery charger function test button and turned off when the battery charger is determined to be functional;
a second power supply configured to supply power to the battery charger function test button and the diagnostic self test circuit; and
at least one diagnostic indicator.

2. The self diagnostic battery charging system of claim 1, wherein the battery charger function test button comprises:
a circuit configured for informing the control circuit board of the self test is invoked.

3. The self diagnostic battery charging system of claim 1, further comprising:
a second diagnostic self test circuit configured to test an electronic battery load.

4. The self diagnostic battery charging system of claim 3, wherein the second diagnostic self test circuit configured to test an electronic battery load comprises:
a second diagnostic self test circuit configured to test battery voltage.

5. The self diagnostic battery charging system of claim 3, wherein the second diagnostic self test circuit configured to test an electronic battery load comprises:
a second diagnostic self test circuit configured to test battery current.

6. The self diagnostic battery charging system of claim 1, wherein the at least one diagnostic indicator comprises:
at least one fault light.

7. The self diagnostic battery charging system of claim 6, wherein the at least one fault light comprises:
at least one fault light indicating an AC power fault to the battery charger.

8. The self diagnostic battery charging system of claim 1, wherein the at least one diagnostic indicator comprises:
at least one error code.

9. A method, comprising:
receiving an indication of a triggered test button configured for initializing a battery charger diagnostic self test circuit, where the triggered test button is communicatively coupled to a battery charger, the battery charger is coupled to a first power source, and the triggered test button and the battery charger diagnostic self test circuit are coupled to a second power source, where the battery charger diagnostic self test circuit includes a fault indicator configured to be initiated by a battery charger function test button and turned off when the battery charger is determined to be functional;
executing a diagnostic program for testing the battery charger subsequent to receiving an indication of a triggered test button;
determining a status of the battery charger from execution of the diagnostic program; and
indicating at least one result from the diagnostic program on at least one diagnostic indicator.

10. The method of claim 9, wherein determining a status of the battery charger from execution of the diagnostic program comprises:
replicating an electronic battery load.

11. The method of claim 10, wherein replicating an electronic battery load comprises:
replicating a current.

12. The method of claim 10, wherein replicating an electronic battery load comprises:
replicating a voltage.

13. The method of claim 9, wherein indicating at least one result from the diagnostic program on at least one diagnostic indicator comprises:
indicating at least one error code.

14. The method of claim 9, wherein indicating at least one result from the diagnostic program on at least one diagnostic indicator comprises:
indicating at least one fault.

15. The method of claim 9, wherein indicating at least one result from the diagnostic program on at least one diagnostic indicator comprises:
indicating an AC power fault.

16. A battery charger, comprising:
a controller;
a diagnostic module having a power supply independent of the controller, where the diagnostic module is configured to diagnose at least one of a battery charger fault or a battery fault;
a diagnostic indicator configured to communicate a diagnosis, including at least one fault indicator where the fault indicator is configured to be initiated by a battery charger function test button and turned off when the battery charger is determined to be functional; and
a battery load module configured for at least one of testing or simulating a battery load.

17. The method of claim 16, wherein diagnostic module having a power supply independent of the controller, where the diagnostic module is configured to diagnose at least one of a battery charger fault or a battery fault comprises:
an AC power supply.

18. The method of claim 16, wherein diagnostic indicator configured to communicate a diagnosis, including at least one fault indicator comprises:
a display screen configured to indicate an error code.

19. The method of claim 16, further comprising:
an overload protector.

20. The method of claim 16, further comprising:
an AC/DC power converter.
